(19) United States
(12) Patent Application Publication
(10) Pub. No.: US 2019/0229428 A1
(43) Pub. Date: Jul. 25, 2019

(54) ANTENNAS HAVING DIELECTRIC SUPPORTS AND AT LEAST ONE METAL LAYER HAVING ONE OR MORE SLOTS THEREIN

(71) Applicant: CommScope Technologies LLC, Hickory, NC (US)

(72) Inventors: Oleg Beskov, South Wales (AU); Deran Gadiagellan, Sydney (AU); Arnold Peregrino, Northryde (AU)

(21) Appl. No.: 16/211,550

(22) Filed: Dec. 6, 2018

Related U.S. Application Data
(60) Provisional application No. 62/620,650, filed on Jan. 23, 2018.

(51) Int. Cl. H01Q 13/10; H01Q 1/50; H05K 1/02; H01Q 1/48

(52) U.S. Cl. CPC H01Q 13/10; H01Q 1/50; H05K 1/028; H01P 3/081; H01Q 1/48; H05K 2201/10098; H05K 2201/09027; H05K 1/0243

(57) ABSTRACT

A slot antenna for a cellular communications system includes a tubular dielectric support that extends along a longitudinal axis, a metal layer substantially circumferentially surrounding the tubular dielectric support, the metal layer including a first longitudinally-extending slot therein in which the metal is omitted and a feed network that includes a transmission line that crosses the first longitudinally-extending slot.

### CROSS-REFERENCE TO RELATED APPLICATION

The present application claims priority under 35 U.S.C. § 119 to U.S. Provisional Patent Application Ser. No. 62/620,650, filed Jan. 23, 2018, the entire content of which is incorporated herein by reference as if set forth in its entirety.

### FIELD

The present invention is directed to communications systems and, more particularly, to antennas for communications systems.

### BACKGROUND

Cellular service is widely available in areas having high or medium population densities, and is increasingly available in even relatively low population density areas. However, due to cost considerations, cellular service is still not available in many remote areas having very low population densities, because the revenues generated from new subscribers that could be obtained by extending service to these areas may be substantially less than the cost of providing cellular service.

Wireless operators, however, may still provide cellular service to remote areas having very low population densities in order to increase the overall coverage of the operator's network. In addition, government entities may mandate that wireless operators provide cellular service to certain remote areas. When extending cellular service to remote areas having very low population densities for purposes of expanding overall coverage and/or complying with government mandates, the goal of the wireless operator may be to design each individual cellular base station to provide coverage over as wide an area as possible, and the capacity of the cellular base station and/or the amount of interference the base station generates with other cellular base stations may not be significant concerns. Cost is obviously another concern, because of the limited revenue that can be generated when extending cellular coverage to very remote areas. Because the goals of a wireless operator in extending cellular coverage to very remote areas often differ from the goals for more typical cellular installations, many of the base station antennas that are suitable for use in typical cellular communications systems may not be well-suited for use in remote areas having very low population densities.

Omnidirectional antennas are often used to provide coverage in remote areas so that a single antenna may be used at each base station, thereby reducing cost. Cellular base stations that are located in remote areas where geographic features limit the size of the cell may use simple, low gain omnidirectional antennas to keep costs low. In remote areas where geographic features allow a single base station to serve a much wider geographic area, higher gain omnidirectional antennas may be used, since higher antenna gain may be necessary to overcome the larger free space propagation losses. Higher antenna gain is typically achieved by providing antennas that have stacked arrays of individual antenna radiating elements.

FIG. 1A is a schematic perspective view of a conventional lower gain slot antenna 10 that is suitable for use in low-capacity, very low population density remote areas such as, for example, the Australian outback, Mongolia or northern Alaska. The antenna 10 comprises a hollow metal tube 20 such as a copper tube that is connected to a radio by a coaxial feed cable 40. The metal tube 20 has a longitudinal slot 32 cut into one side thereof. If the antenna 10 is mounted so that the metal tube 20 extends vertically with respect to a plane defined by the horizon, then the antenna 10 will transmit and receive horizontally polarized signals.

FIG. 1B is an enlarged view showing the configuration of the coaxial feed cable 40 of FIG. 1A and how it is mounted across the longitudinal slot 32. As shown in FIG. 1B, the coaxial feed cable 40 may comprise a conventional coaxial cable that has an inner conductor 42 and an outer conductor 44 that are separated by a dielectric spacer. The jacket 46 of coaxial feed cable 40 (not shown in FIG. 1B but visible in FIG. 1A) may be removed from the coaxial feed cable 40 on either side of the longitudinal slot 32 to expose the outer conductor 44 of the coaxial feed cable 40, and the outer conductor 44 may be soldered or otherwise affixed to the metal tube 20 on either side of the longitudinal slot 32. The jacket 46 and the outer conductor 44 may be removed from the portion of the coaxial feed cable 40 that crosses the longitudinal slot 32 so that only the inner conductor 42 of the coaxial feed cable 40 crosses over the longitudinal slot 32. The distant end of the coaxial feed cable 40 is an open circuit, as shown in FIG. 1B.

The slot antenna 10 of FIGS. 1A-1B may generate an antenna beam that provides omnidirectional coverage in the azimuth plane and directional coverage in the elevation plane. In other words, the antenna beam generated by the slot antenna 10 may extend outwardly from the slot antenna 10 in a direction that is parallel to the plane defined by the horizon in a circle that extends all the way around the slot antenna 10, while the antenna beam may be “directional” in the elevation plane such that the antenna beam only provides coverage for a limited range of elevation angles. FIG. 1C illustrates the azimuth and elevation patterns of an antenna beam that is omnidirectional in the azimuth plane and directional in the azimuth plane. FIG. 1C also includes a three dimensional representation of the antenna beam for clarity. Antenna beams having shapes similar to that shown in FIG. 1C may be well-suited for use in remote areas because the antenna beam will extend with high gain along the surface of the earth—which is where users will typically be located—while not extending as much into the ground or at high elevation angles into the sky.

Higher gain antennas that generate omnidirectional antenna beams in the azimuth plane are also known in the art. For example, CommScope® sells UNA008R and UNA010F-0-V2 antennas that generate vertically polarized antenna beams that provide full 360° coverage in the azimuth plane. These antennas may have a narrow beamwidth in the elevation plane of, for example, 7-10° (and do not use slot radiating elements). CommScope® likewise sells LNX003U-V2 antennas that include a first array of three horizontally polarized radiating elements and a second array of three vertically polarized radiating elements, where each radiating element is implemented as a slot in a brass tube. These antennas may be relatively heavy and expensive to manufacture due to the size of the metal tube required to accommodate the two arrays of radiating elements.

While remote, low population areas are one application for antennas that generate antenna beams having omnidirectional coverage in the azimuth plane and directional coverage in the elevation plane, another application for such antennas is in so-called small cell base stations (which are also sometimes referred to as microcell base stations). A small cell base station refers to a low-power base station that may operate in the licensed and/or unlicensed frequency spectrum that has a much smaller range than a typical “macro cell” base station. A small cell base station may be designed, for example, to serve users who are within tens or hundreds of meters of the base station. Small cell base stations may be used, for example, to provide cellular coverage to high traffic areas within a macro cell, which allows the macro cell base station to offload much or all of the traffic in the vicinity of the small cell base station.

### BRIEF DESCRIPTION OF THE DRAWINGS

FIG. 1A is a schematic perspective view of a conventional omnidirectional slot antenna.

FIG. 1B is an enlarged view showing the configuration of the coaxial feed cable that is used to feed radio frequency (“RF”) signals to and from the conventional omnidirectional slot antenna of FIG. 1A.

FIG. 1C provides several views of an antenna beam that has an omnidirectional pattern in the azimuth plane and a directional pattern in the elevation plane.

FIG. 2 is a schematic perspective view of a slot antenna according to certain embodiments of the present invention.

FIG. 3A is a perspective view of a slot antenna according to further embodiments of the present invention.

FIG. 3B is a longitudinal cross-sectional view of the slot antenna of FIG. 3A with a tubular dielectric support thereof omitted.

FIG. 3C is a plan view of a flexible printed circuit board of the slot antenna of FIGS. 3A-3B.

FIG. 3D is a cross-sectional view of the flexible printed circuit board taken along line 3D-3D of FIG. 3C.

FIG. 4 is a perspective view of a slot antenna according to further embodiments of the present invention during an intermediate step in the assembly thereof.

FIG. 5 is a perspective view of a slot antenna according to still further embodiments of the present invention.

FIG. 6A is a perspective view of a slot antenna according to yet additional embodiments of the present invention.

FIG. 6B is a plan view of a printed circuit board of the feed network of the slot antenna of FIG. 6A.

FIG. 6C is a perspective view of a modified version of the slot antenna of FIGS. 6A-6B.

FIGS. 7A-7F are schematic diagrams illustrating additional example slot designs that may be employed in the slot antennas according to embodiments of the present invention.

FIG. 8 is a perspective view of a slot antenna according to still further embodiments of the present invention.

FIG. 9 is a schematic view of a slot antenna according to yet additional embodiments of the present invention.

### DETAILED DESCRIPTION

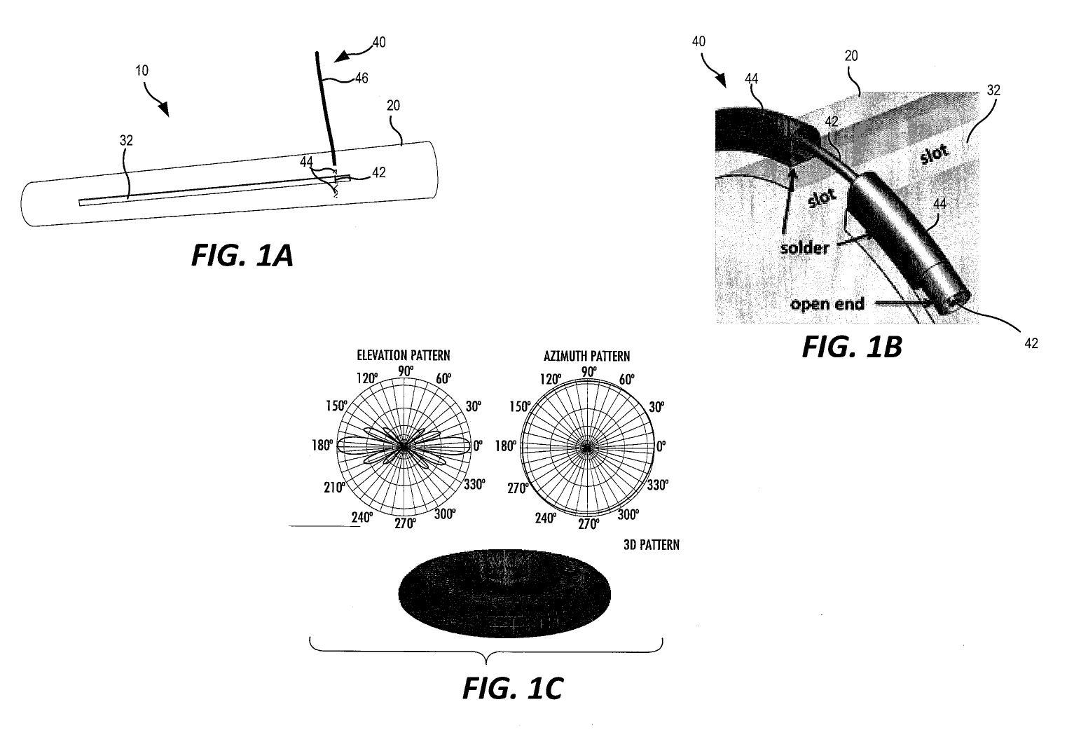

The conventional slot antenna 10 of FIGS. 1A-1B that is discussed above may be heavy and expensive to fabricate. Moreover, the conventional slot antenna 10 may be expensive to design, since individual prototypes are expensive to manufacture and expensive to modify, and manufacturing issues may limit the designs that are available for the slot 32. Since the antenna 10 may be used to service remote areas that typically have few subscribers, these expense issues may be a significant concern. Cost concerns may likewise arise if the conventional slot antenna 10 is used as the antenna for small cell base stations, as large numbers of such base stations are currently being deployed and hence cost may also be a concern in the small cell environment due to the large number of antennas used.

Pursuant to embodiments of the present invention, omnidirectional slot antennas are provided that are suitable for use as base station antennas. These antennas may be formed using flexible printed circuit boards or other metal-on-dielectric technologies. In an example embodiment, the flexible printed circuit board may be mounted on the inside or outside of a tubular dielectric support such as a plastic tube. The tubular dielectric support may have circular transverse cross-sections in some embodiments, but tubes with other cross-sections may also be used (e.g., square, hexagonal, octagonal, oval, etc.). The tubular dielectric support may be solid or may have a hollow interior. One or more “slots” may be formed in the flexible printed circuit board by selectively etching away a metal layer thereof to form the slot(s). The use of flexible printed circuit boards to form the slot antenna allows for slots having any desired shape without raising any manufacturing issues, as any desired “slot” shape may be readily formed on a flexible printed circuit board using conventional fabrication techniques. Additionally, different slots designs may be easily and inexpensively formed and tested so that optimal slot patterns may be readily identified.

In some embodiments, the flexible printed circuit board may include a feed that is used to pass RF signals to and from the slot. In other embodiments, the flexible printed circuit board may be a first flexible printed circuit board and the antenna may further include a second flexible printed circuit board that is used to implement at least part of the feed network for the antenna. In such embodiments, the first flexible printed circuit board (i.e., the flexible printed circuit board that includes one or more slots) may circumferentially surround the inner or outer diameter of the tubular dielectric support, and the second flexible printed circuit board (i.e., the flexible printed circuit board with the feed network) may be arranged, for example, concentrically with the first flexible printed circuit board (and may be either inside or outside the tubular dielectric support). A power divider network may be formed on the second flexible printed circuit board in embodiments where the first flexible printed circuit board includes a plurality of slots that form an antenna array (i.e., each different slot acts as a radiating element of an antenna array). In an example embodiment, the power divider network may have an input and eight outputs. Respective wires may be soldered to the eight outputs, and may be used to carry the sub-components of an RF signal to the respective slots to form a wire-over-ground type transmission line. In further embodiments, other types of feed networks may be used such as, for example, the coaxial feed cable of the conventional slot antenna 10 discussed above with reference to FIGS. 1A-1B. The antennas according to embodiments of the present invention may be lightweight and easy to manufacture, and may be designed to have low gain or higher gain by varying the number of slot radiating elements.

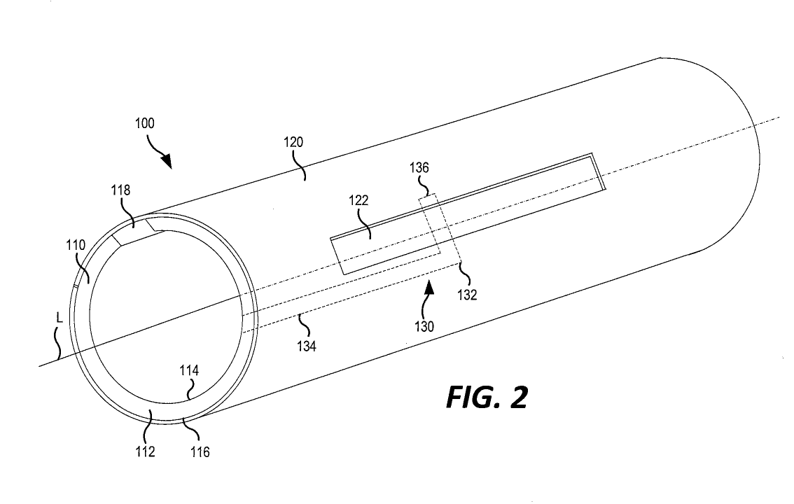

Embodiments of the present invention will now be discussed in greater detail with reference to FIGS. 2-9, which depict example embodiments of the invention.

FIG. 2 is a schematic perspective view of a slot antenna 100 according to certain embodiments of the present invention. The slot antenna 100 may generate an antenna beam that provides omnidirectional coverage in the azimuth plane and that provides a suitable beamwidth in the elevation plane. The elevation beamwidth may be controlled by the length of the slot included in a metal layer of the antenna 100.

By way of background, slot antennas are a known type of antenna that may radiate in a manner similar to a conventional dipole antenna. A slot antenna may comprise a metal surface, such as a flat metal plate or a metal tube, that has one or more holes or slots cut out of the metal. When an RF signal is fed to the antenna, the slot radiates electromagnetic energy. If the antenna includes a single linear slot, the polarization of the emitted electromagnetic radiation is linear. The configuration of the slot (e.g., the shape and size thereof) and the configuration of the cavity behind the slot determine the radiation pattern of the antenna. A signal carrying trace of an RF transmission line such as, for example, a microstrip transmission line, may be placed across the short side of the slot exciting it with an open stub. When an electromagnetic signal is applied to the transmission line, an electric field distribution is induced within the slot, and currents travel around the perimeter of the slot. Both contribute to the emitted radiation. Slot antennas provide an omnidirectional pattern in the azimuth plane with a directional elevation pattern (the beamwidth of which may be controlled by adjusting, for example, the length of the slot) and hence may be well-suited for certain cellular communications applications.

Referring now to FIG. 2, the slot antenna 100 includes a tubular dielectric support 110, a metal layer 120 and a feed network 130. As shown, the tubular dielectric support 110 may comprise a hollow, elongated tube 112 having a circular transverse cross-section that extends along a longitudinal axis L. The tube 112 has an inner surface 114 and an outer surface 116. The tube 112 may have solid sidewalls or may have a mesh structure. The tube 112 may or may not be hollow (it is hollow in the depicted embodiment). The tube 112 may be formed of a dielectric material such as, for example, a plastic material. As shown, in some embodiments, the tube 112 may have one or more longitudinally-extending slots 118. The tube 112 may have circular transverse cross-sections or other transverse cross-sections.

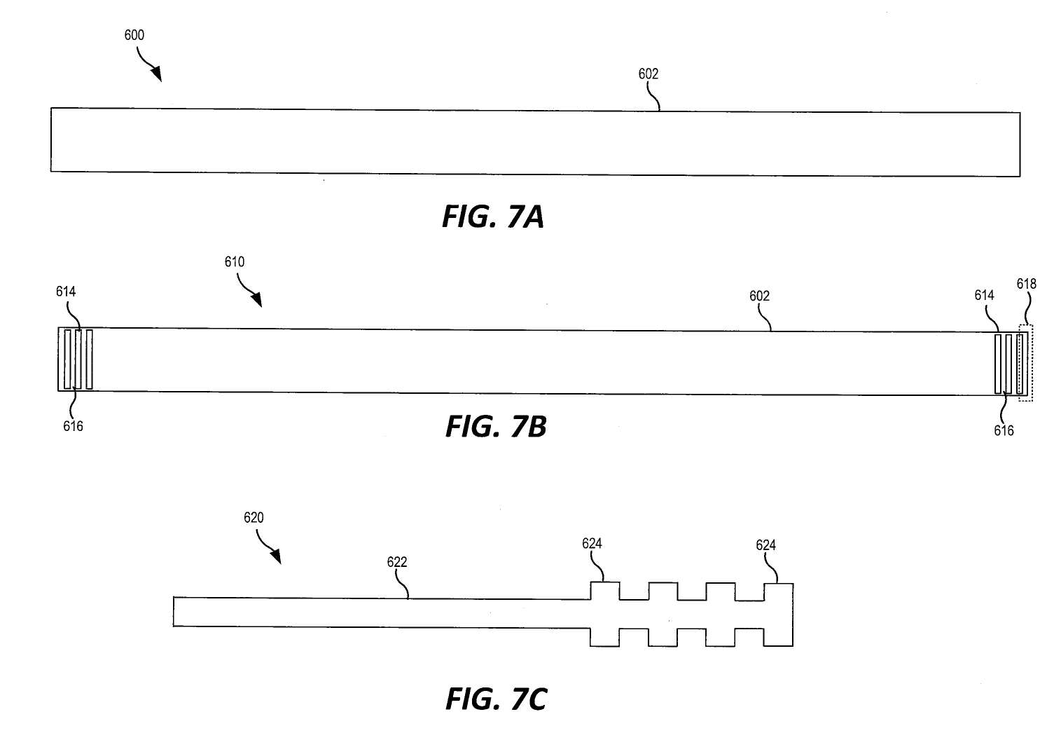

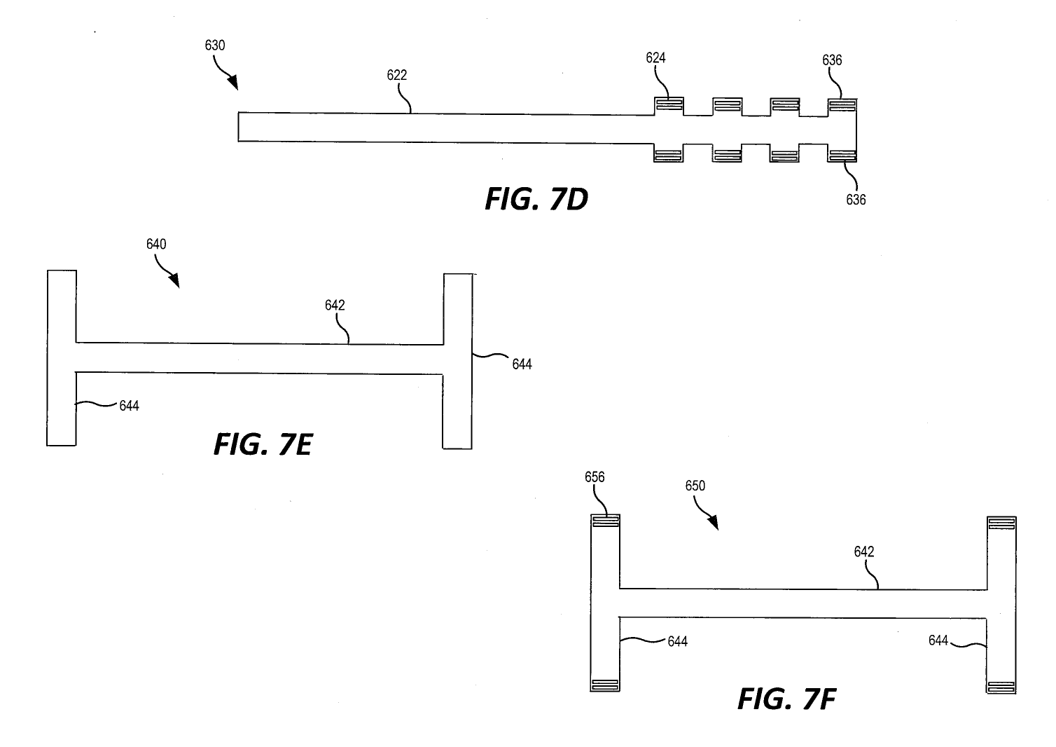

The metal layer 120 may comprise a thin layer of metal that substantially surrounds the outer surface 116 or, alternatively, may be on the inner surface 114 of the tubular dielectric support 112. If the metal layer 120 is on the inner surface, the tubular dielectric support 110 may be formed of a material that is substantially transparent to RF energy at the operating frequencies of the antenna 100. In the depicted embodiment, the metal layer 120 circumferentially surrounds the outer surface 116 of the tube 112 and is concentrically arranged with respect to the tube 112. The metal layer 120 may comprise, for example, a copper layer. The metal layer 120 may include a first slot 122 therein in which the metal is omitted. In some embodiments, the first slot 122 may be a longitudinally-extending slot 122 as shown in FIG. 2. The metal layer 120 may also include additional slots (not shown in FIG. 2) where the metal is omitted. These additional slots may take on a variety of different shapes. Example embodiments of slot patterns in a metal layer that can be used to form slot antennas according to example embodiments of the present invention are discussed below with reference to FIGS. 7A-7F. The slot 122 of antenna 100 of FIG. 2 could be replaced with any of the slot designs shown in FIGS. 7A-7F or with any other appropriate slot design.

The feed network 130 may comprise, for example, a transmission line 130 that is coupled to a radio (not shown) of the base station. The transmission line 130 may comprise, for example, a metal trace 132 that extends along the tubular dielectric support 110 so that it is spaced apart from the metal layer 120 that includes the first slot 122. A coaxial cable (not shown) may connect the transmission line 130 to the radio or to other equipment such as, for example, a tower-mounted diplexer. A center conductor of the coaxial cable may connect to (e.g., by soldering) the metal trace 132 of the transmission line 130. The ground conductor of the coaxial cable may connect to (e.g., by soldering) the metal layer 120. The metal trace 132 may include a first segment 134 that extends longitudinally through the tubular dielectric support 110 and a second segment 136 that may extend transversely across the first slot 122. The transmission line 130 may be any transmission line capable of carrying RF signals including microstrip transmission lines, stripline transmission lines, metal wires, cables, etc.

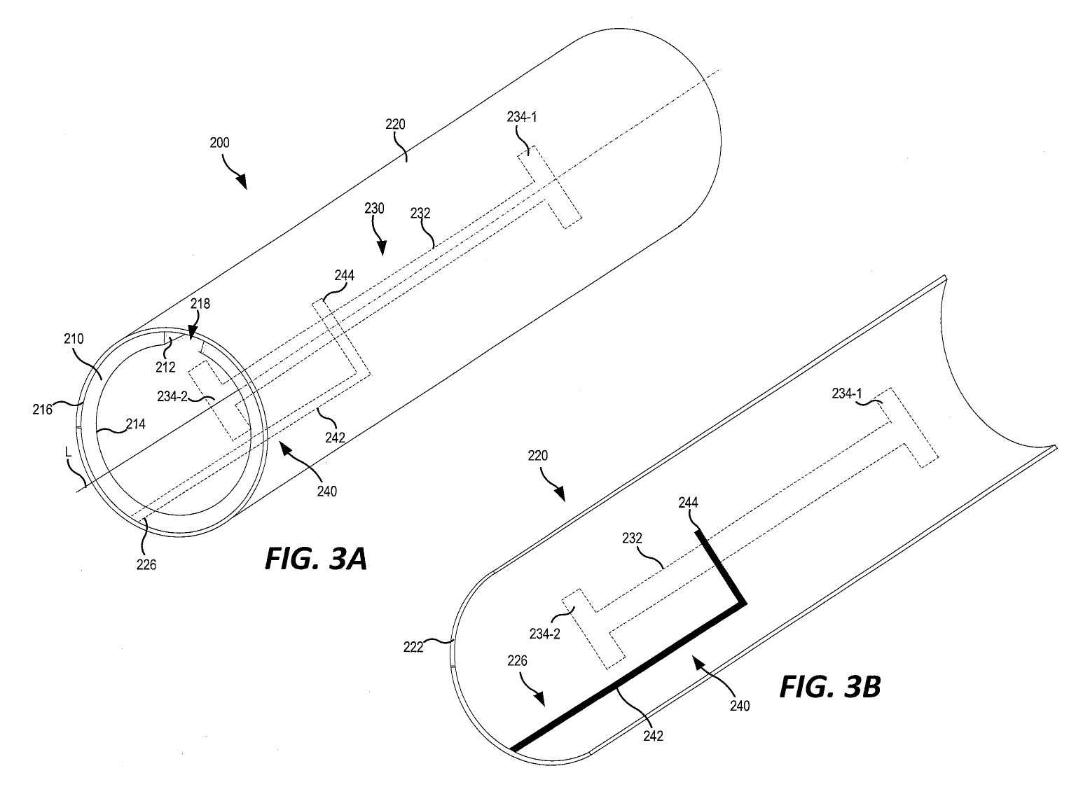

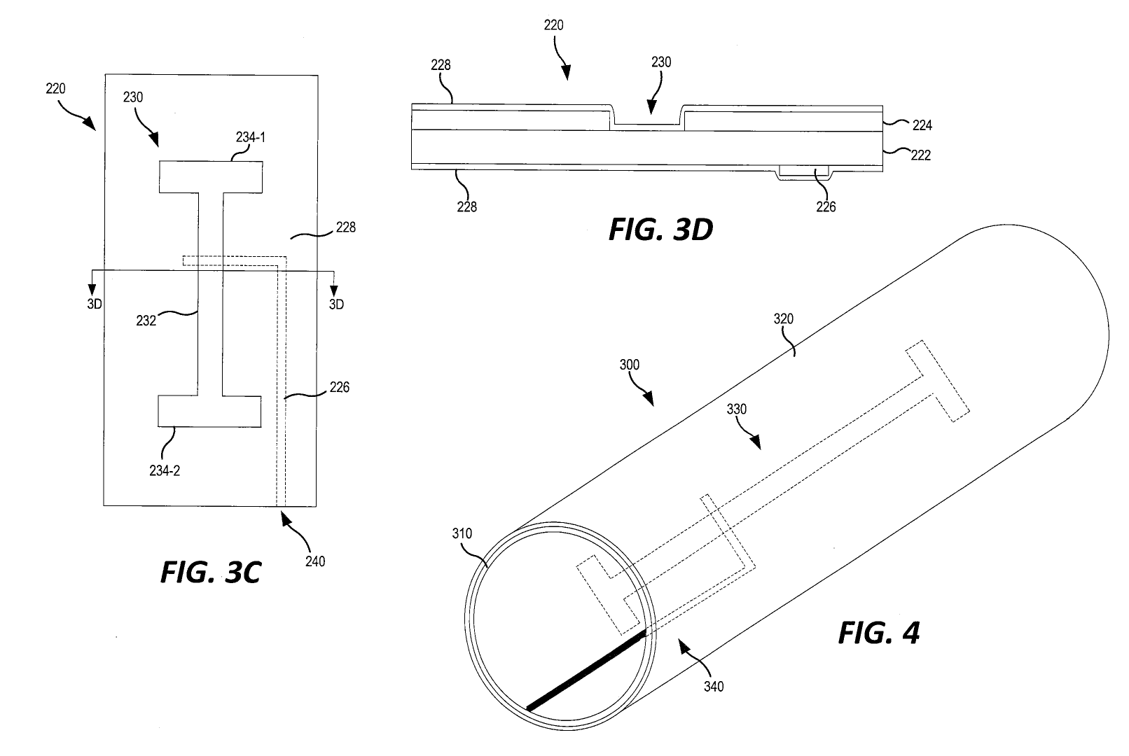

FIGS. 3A-3D illustrate a slot antenna 200 according to another example embodiment of the present invention. In particular, FIG. 3A is a perspective view of the slot antenna 200, and FIG. 3B is a longitudinal cross-sectional view of the slot antenna 200 of FIG. 3A with a tubular dielectric support thereof omitted. FIG. 3C is a plan view of a flexible printed circuit board of the slot antenna 200, and FIG. 3D is a cross-sectional view of the flexible printed circuit board taken along line 3D-3D of FIG. 3C.

As shown in FIG. 3A, the slot antenna 200 includes a tubular dielectric support 210 and a flexible printed circuit board 220. The tubular dielectric support 210 comprises an elongated, hollow dielectric tube 212 having a circular transverse cross-section that extends along a longitudinal axis L. The tube 212 has an inner surface 214 and an outer surface 216. The tube 212 is pictured as having solid sidewalls, but it may have cutouts and/or a mesh structure in other embodiments. In the depicted embodiment, the tube 212 only extends for about 330° and hence includes a longitudinally-extending slot 218.

Referring to FIGS. 3B-3D, the flexible printed circuit board 220 may comprise a thin, flexible dielectric substrate 222 that has a metal layer 224 (e.g., a copper layer) on a first side thereof and a metal trace 226 on a second side thereof that is opposite the first side. A thin coating of a dielectric material 228 may be formed over one or both of the metal layer 224 and the metal trace 226 to protect the metal layer 224 and/or the metal trace 226 from damage and/or environmental effects (e.g., exposure to air or water that may lead to oxidation or other chemical changes to the metal). The flexible printed circuit board 220 may be wrapped around the exterior of the tubular dielectric support 210 so that it substantially circumferentially surrounds the tubular dielectric support 210. The metal layer 224 may include a slot 230 formed therein in which the metal is omitted. The slot 230 may be, for example, a generally longitudinally-extending slot 230 as shown in FIGS. 3A-3C. In the depicted embodiment, the slot 230 includes not only a longitudinally-extending portion 232, but further includes a pair of transversely extending portions 234-1, 234-2 that connect to either end of the longitudinally-extending portion 232. The transverse portions 234 may effectively extend the length of the longitudinal portion 232 without requiring a corresponding increase in the length of the antenna 200. The longitudinally-extending portion 232 and the transversely extending portions 234-1, 234-2 may together form the slot 230 to have an “I” shape or an “H” shape. It will be appreciated that only one transverse portion 234 may be provided in other embodiments, and that the transverse and longitudinal portions 232, 234 need not be perpendicular to each other. Note that herein when multiple like elements are provided they may be designated with two-part reference numerals, and these elements may be referred to individually by their full reference numeral (e.g., transverse slot 234-2) and collectively by the first part of their reference numerals (e.g., the transverse slots 234).

The metal trace 226 may comprise a thin copper trace in an example embodiment. The metal trace 226 may, in conjunction with the flexible dielectric substrate 222 and the metal layer 224, form a transmission line 240. A coaxial cable (not shown) may connect the transmission line 240 to a radio (not shown) of the base station antenna or to other equipment such as, for example, a tower-mounted diplexer. The metal trace 226 (and hence the transmission line 240) may include a first portion 242 and a second portion 244. The first portion 242 of the transmission line 240 may, for example, extend longitudinally along the exterior of the tubular dielectric support 210 and the second portion 244 of the transmission line 242 may extend transversely across the longitudinal portion 232 of the slot 230. While the transmission line 240 is formed as part of the flexible printed circuit board 220 in the above described embodiment, it will be appreciated that in other embodiments the transmission line 240 may be implemented separately from the flexible printed circuit board 220. Typically the flexible printed circuit board 220 would be mounted on the tubular dielectric support 210 so that the metal layer 224 was formed on the outside of the flexible printed circuit board 220 and the metal trace 226 was formed on the inside of the flexible printed circuit board 220 (i.e., the portion of the flexible printed circuit board 220 that is adjacent the tubular dielectric support 210). However, if the flexible dielectric substrate 222 is sufficiently thin, this arrangement may be reversed. The flexible printed circuit board 220 may also be mounted on the inside of the tubular dielectric support 210 in other embodiments.

The antenna 200 may operate as follows. An RF signal is generated by a radio (not shown) and passed to the antenna 200 via, for example, a coaxial cable (also not shown). The ground conductor of the coaxial cable may be connected (e.g., by soldering) to the metal layer 224 of flexible printed circuit board 220 and the center conductor of the coaxial cable may be connected (e.g., by soldering) to the metal trace 226 on the opposite side of flexible printed circuit board 220. As described above, the metal trace 226 crosses the longitudinal portion 232 of the slot 230. The location where the metal trace 226 crosses the slot 230 may be selected based on the impedance matching characteristics of the transmission line 240 to the slot 230. The edges of the slot 230 form a balanced transmission line which is loaded by a distributed shunt inductive reactance. The voltages applied to the opposite edges of the slot 230 in response to application of an RF signal to the transmission line 240 generates circumferential currents that flow on the metal cylinder that is formed by metal layer 224. Since these currents may be very nearly in-phase, the overall behavior of the metal cylinder (with slot 230 therein) formed by metal layer 224 may be very similar to that of an array of small, closely stacked loops which generate a nearly omnidirectional antenna beam in the azimuth plane. The elevation beamwidth of the antenna beam may primarily be determined by the length of the slot 230. The pair of transversely extending portions 234-1, 234-2 that connect to either end of the longitudinally-extending portion 232 of the slot 230 allow the length of the longitudinally-extending portion 232 of the slot 230, and hence the length of the antenna 200, to be reduced, albeit with potentially a slight degradation in either or both the gain of the antenna 200 and/or the cross-polarization performance thereof. Decreasing the size of the antenna 200 has cost and other benefits, and also may provide a reduction in grating lobe effects in antennas that include a plurality of slots in a stacked array (as discussed later in the present disclosure). It will also be appreciated that pursuant to further embodiments of the present invention the slot 32 of the conventional antenna 10 of FIG. 1 (in which the slot is formed in a hollow metal tube) may be replaced with a the slot 230 or any of the other slot designs disclosed herein the include both a longitudinally extending portion as well as at least one generally transversely extending portion. This may allow a reduction in the length of the conventional antenna 10.

The slot antenna 200 may have a number of advantages as compared to the conventional slot antenna 10 of FIG. 1. First, the antenna 200 may be cheaper and lighter than the conventional slot antenna 10. The transverse slots 234 may allow a reduction in the length of the antenna 200 while maintaining the performance thereof. The tubular dielectric support 210 may be formed as a thin plastic tube that may be both lightweight and inexpensive. The flexible printed circuit board 220 may also be lightweight, and may be significantly less expensive than the copper tube 20 used in the conventional antenna 10. The microstrip feed line 240 may also be inexpensive and may be implemented on the same flexible printed circuit board 220 used to form the slot antenna 200. Second, the antenna 200 may be readily formed to have essentially any desired slot design, since the slot 230 may be created by the masking process used in the fabrication of the flexible printed circuit board 220. In contrast, with the conventional slot antenna 10, the slot design may be constrained by manufacturing capabilities to cut slots 32 into metal tubes 20, and reconfiguring the equipment to form different slot designs may be more burdensome.

The flexible printed circuit board 220 may be mounted onto the tubular dielectric support 210 in any appropriate way. For example, in some embodiments, mechanical mounting mechanisms such as screws, rivets, cable ties and the like may be used to affix the flexible printed circuit board 220 to an outer (or, alternatively, inner) surface of the tubular dielectric support 210. In other embodiments, adhesives such as epoxies, glues, double-sided adhesive tapes and the like may be used to affix the flexible printed circuit board 220 to the surface of the tubular dielectric support 210. In still other embodiments, a laminate could be applied over the flexible printed circuit board 220 to encapsulate the flexible printed circuit board 220 and the tubular dielectric support 210.

The slot antenna 200 that is discussed above is formed using a flexible printed circuit board 220. Pursuant to further embodiments, of the present invention, slot antennas are provided that are formed using other technologies for selectively plating metal on a dielectric substrate.

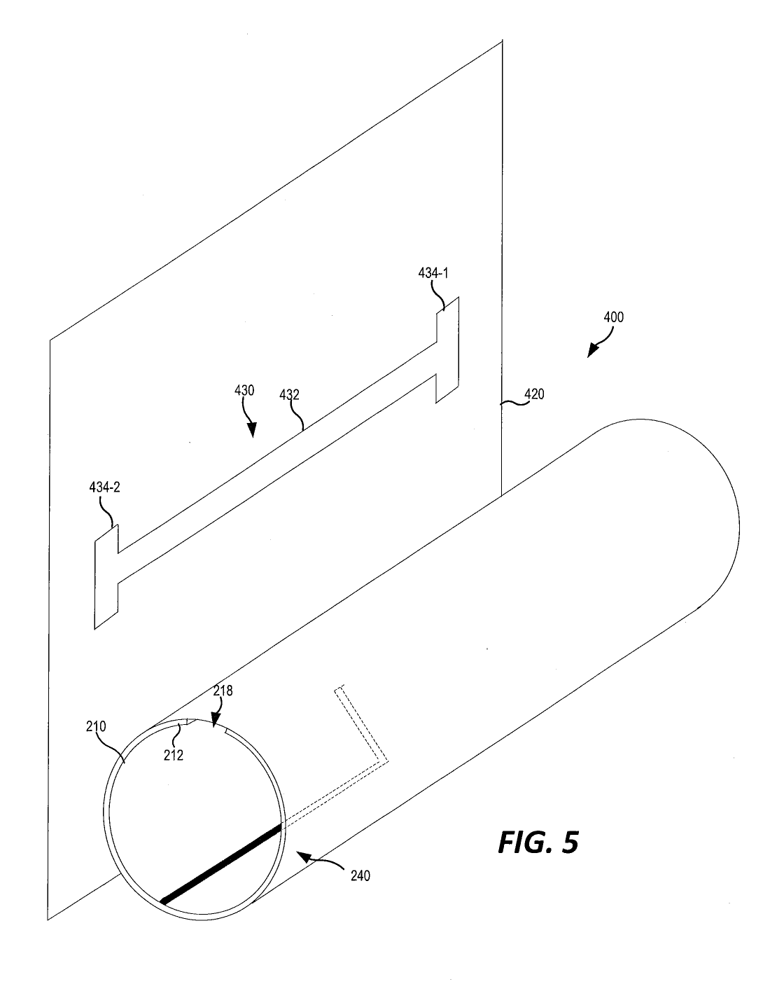

For example, FIG. 4 is a perspective view of a slot antenna 300 according to further embodiments of the present invention that is formed using laser direct sintering or other techniques for selectively plating metal (e.g., copper) onto a dielectric substrate. The slot antenna 300 includes a tubular dielectric support 310, a metal layer 320 and a transmission line 340. As shown in FIG. 4, the slot antenna 300 may look almost identical to the slot antenna 200 of FIGS. 3A-3D, except that the slot 218 in the tubular dielectric support 210 of antenna 200 is omitted in the tubular dielectric support 310, and the flexible printed circuit board 220 of antenna 200 is replaced in antenna 300 with a layer of plated metal 320 that is deposited on the outer surface of the tubular dielectric support 310, where the metal in the plated metal layer 320 is selectively omitted to form a slot-shaped region 330 on the outer surface of the tubular dielectric support 310 that is free of metal. The transmission line 340 may be implemented, for example, as a metal trace that extends within the interior of the tubular dielectric support 310. In some embodiments, the transmission line 340 may be a separate piece that is affixed to the interior of the tubular dielectric support 310. In other embodiments, the transmission line 340 may be formed by laser direct sintering or some other technique to be integral with the tubular dielectric support 310. The tubular dielectric support 310 may include one or more longitudinal slots and/or transverse slots (not shown) to facilitate forming the transmission line 340 (e.g., by laser direct sintering).

In some embodiments, the metal may be selectively deposited on the tubular dielectric support 310 using laser direct structuring. With laser direct structuring, a thermoplastic material is used to form the tubular dielectric support 310 and this thermoplastic material may be doped with a metal-plastic additive material that may be activated by means of a laser. The portions of the tubular dielectric support 310 where metal is to be deposited may be treated by a laser which creates micro-scale roughness on the surfaces of the tubular dielectric support 310. The metal particles from the metal-plastic additive material that are present in these roughened areas serve as a seed layer for subsequent metallization. The metallization process may use an electroless metal bath (e.g., a copper bath) to deposit copper on the roughened areas treated by the laser. Successive layers of metal such as, for example, copper may then be formed on the initial metal layer to form the metal layer 330.

While laser direct structuring is one technique that may be used to form the layer of plated metal 320 having the slot-shaped metal-free region 330 and/or the transmission line 340, different techniques for selectively metalizing a three-dimensional plastic frame may be used such as vacuum metallization, electroplating, microscopic integrated processing technology, 3-D printing and the like in other embodiments.

Pursuant to still further embodiments, the metal layer having the slot may be formed using conventional metal stamping and rolling techniques. FIG. 5 is a perspective view of a slot antenna 400 according to still further embodiments of the present invention that depicts such an antenna during an intermediate step in the fabrication thereof (namely before metal sheet 420 is wrapped around the tubular dielectric support 210). As shown in FIG. 5, the slot antenna 400 includes a metal layer 420 that is formed by stamping thin sheet metal material. The slot antenna 400 may include a tubular dielectric support and a microstrip transmission line that are identical to the tubular dielectric support 210 and microstrip transmission line 240, respectively, that are described above. Accordingly, further discussion of these elements of antenna 400 will be omitted. As is further shown in FIG. 5, a thin piece of sheet metal 420 such as a thin piece of copper may be cut to have a length equal to the length of tubular dielectric support 210 and a width that is approximately equal to the circumference of the tubular dielectric support 210. This cut sheet 420 of metal may then be stamped to have a slot 430 formed therein. The slot 430 may have any appropriate shape. In the depicted embodiment, the slot 430 includes a longitudinally-extending section 432 and a pair of transversely extending portions 434-1, 434-2 that connect to either end of the longitudinally-extending portion 432 so that the slot 430 has an “I” shape. The sheet 420 may then be rolled around the exterior (or interior) of the tubular dielectric support 210 and held in place by any appropriate means such as an adhesive, a one-sided strip of adhesive tape applied along the seam where the ends of the metal sheet 420 meet after the sheet is rolled around the tubular dielectric support 210, a two-sided adhesive tape, a thin plastic tube that is inserted over the rolled metal sheet 420, etc.

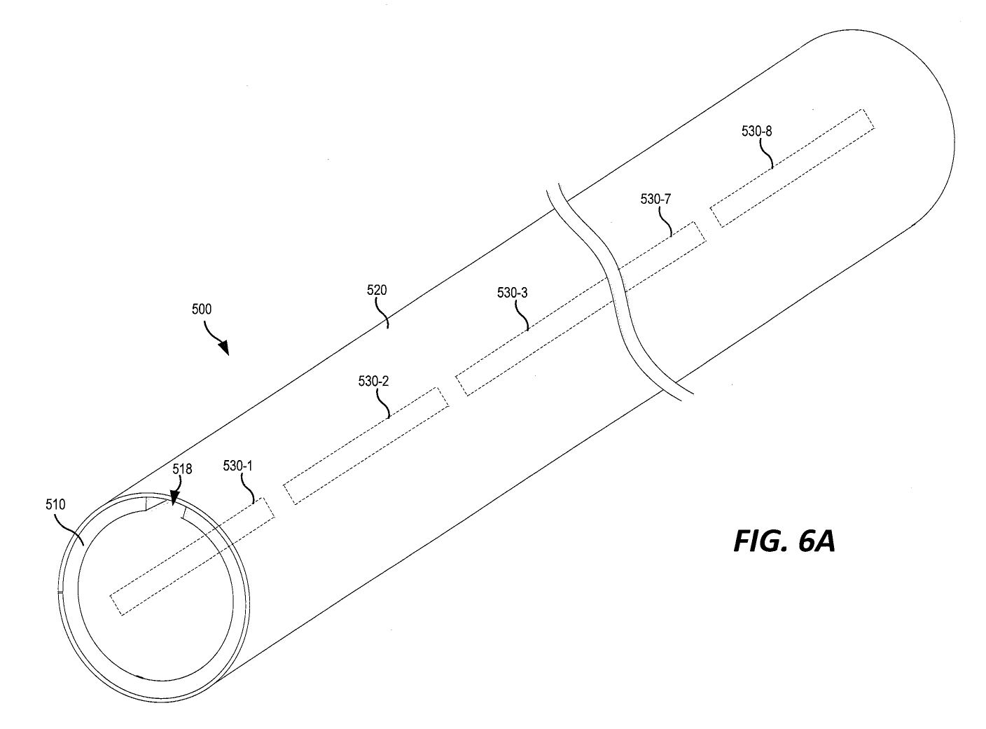

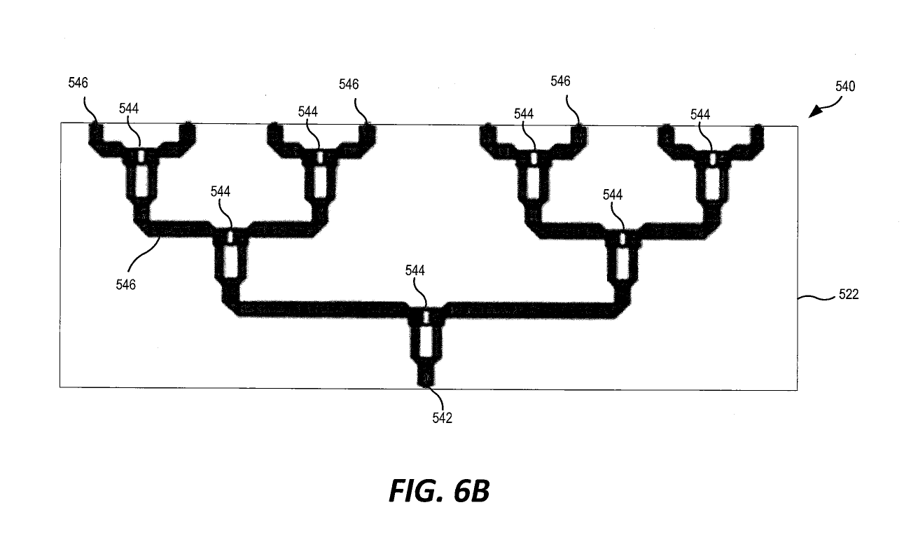

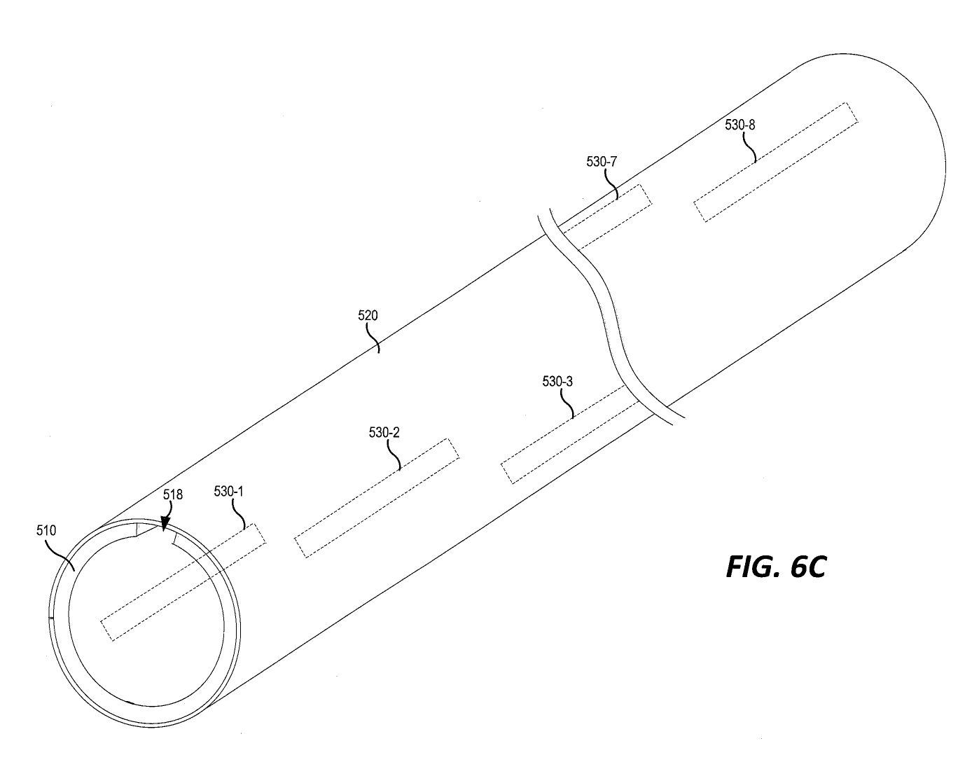

FIGS. 6A-6B illustrate a slot antenna 500 according to further embodiments of the present invention that includes multiple radiating slots 530. In particular, FIG. 6A is a perspective cut-away view of the slot antenna 500, and FIG. 6B is a plan view of one side of the flexible printed circuit board of the slot antenna 500 that includes the feed network for the slot antenna 500.

As shown in FIG. 6A, the slot antenna 500 is similar to the above-described slot antenna 200 in that the antenna 500 includes a tubular dielectric support 510 and a flexible printed circuit board 520. However, as can be seen in FIGS. 6A-6B, the antenna 500 includes a plurality of slots 530 instead of the single slot included in each of antennas 200, 300, 400. The slots 530 are arranged in a straight line longitudinally along the tubular dielectric support 510 with a uniform distance between adjacent slots 530 (i.e., the slots 530 are arranged at a uniform pitch). By forming multiple slots 530 in the metal layer 524 of the flexible printed circuit board 520, the slot antenna 500 is formed as a phased array antenna, where each slot 530 constitutes a separate radiating element thereof. As a result, the antenna 500 may exhibit higher gain (since it includes multiple radiating elements) and the phases of respective sub-components of an RF signal that are fed to the individual radiating elements (i.e., the slots 530) may be set to shape the antenna beam in a manner well known to those of skill in the art.

In the embodiment of FIGS. 6A-6B, longitudinally-extending linear slots 530 extend longitudinally along the tubular dielectric support 510 at a uniform pitch. It will be appreciated that numerous other configurations are possible. For example, in another embodiment, the slots 530 could be arranged to have a non-uniform pitch (i.e., the distance between adjacent pairs of slots 530 may vary). As yet another example, the slots 530 need not extend in a straight line, but may instead be rotated with respect to one another according to a pattern of rotation, as is shown in FIG. 6C. The pitch may be uniform or non-uniform in such embodiments. Different designs for the slots 530 may be used, as is discussed below with reference to FIGS. 7A-7F. Thus, it will be appreciated that the phased array slot antenna 500 is just one example implementation.

The flexible printed circuit board 520 may include a dielectric substrate 522 that has a metal layer 524 with slots 530 therein on one side thereof. In the depicted embodiment, a total of eight slots 530-1 through 530-8 are provided (only five of which are fully or partially shown in the cut-away view of FIG. 6A). Each slot 530 may be fed by a separate branch in the feed network 540. The feed network 540 is not shown in FIG. 6A to simplify the drawing, but instead is shown in FIG. 6B.

The feed network 540 (see FIG. 6B) is used to feed RF signals from a radio to the respective slots 530 of the slot antenna 500. The feed network 540 may be formed on the side of the dielectric substrate 522 of the flexible printed circuit board 520 that is opposite the metal layer 524. As shown in FIG. 6B, the feed network 540 may comprise, for example, a branch network of seven power dividers 544 that may split an RF signal input thereto into eight sub-components on the transmit path, and which may combine eight sub-components of an RF signals into a single RF signal on the receive path. The power dividers 544 may be implemented, for example, as Wilkinson power dividers or any other suitable printed circuit board based power divider. The power dividers 544 may be formed on the side of the dielectric substrate 522 of flexible printed circuit board 520 that is opposite the metal layer 524 with the slots 530 therein. The flexible printed circuit board 520 may include an input pad 542 and a plurality of output stubs 546. The input pad 542 may connect to the radio (through, for example, a coaxial cable). A center conductor of the coaxial cable may be connected to the input pad 542, and the ground conductor of the coaxial cable may be connected to the metal layer 524 on the printed circuit board 520 that includes the slots 530. The seven power dividers 544 may divide an RF signal input at the input pad 542 into eight sub-components (which may or may not be of equal magnitude) that are fed to the output stubs 546. Each output stub may transversely cross a respective one of the slots 530 in the manner shown in FIG. 3B above.

In the above-described embodiment, the feed network 540 is formed on the flexible printed circuit board 520. In other embodiments, the feed network 540 may be formed separately. For example, the feed network 540 could be formed on a second printed circuit board (which may or may not be a flexible printed circuit board). If a second flexible printed circuit board is used to implement the feed network 540, the second flexible printed circuit board may be rolled into a cylinder (or a portion of a cylinder) and inserted, for example, (1) into the interior of the tubular dielectric support 510, (2) between the tubular dielectric support 510 and the flexible printed circuit board 520, or (3) rolled around the outside of the flexible printed circuit board 520.

In embodiments in which the feed network 540 is implemented separately from the flexible printed circuit board 520, the feed network 540 may, in some cases, be inserted within an interior of the tubular dielectric support 510. In such embodiments, the tubular dielectric support 510 may include a longitudinal slot 518 that may provide better access to the interior of the tubular dielectric support 510 to facilitate mounting the feed network 540 therein. The flexible printed circuit board 520 may cover the longitudinal slot 518 in the tubular dielectric support 510.

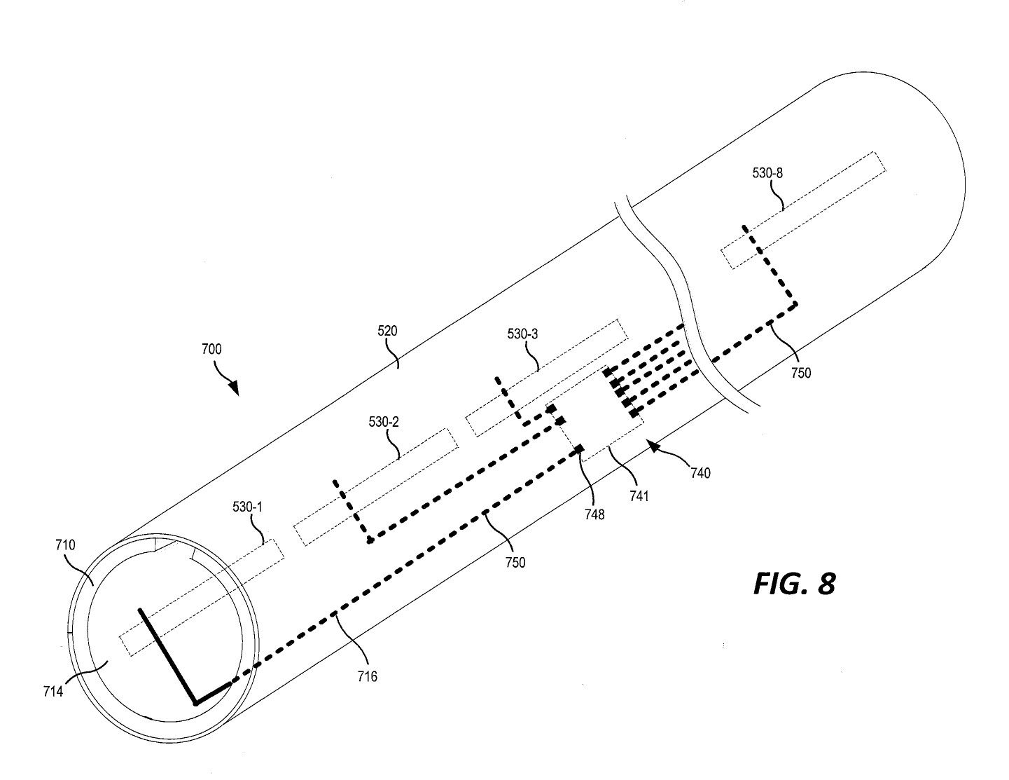

In some embodiments, the feed network 540 may be implemented on a small printed circuit board as a cascaded series of power dividers in a manner similar to that described above with respect to FIG. 6B. In some embodiments, instead of using a large printed circuit board (as in the case of the embodiment of FIG. 6B) that extends a significant portion of the length of the antenna 500 so that the stubs 546 may cross the respective slots 530, the stubs 546 may instead be used as output pads. For example, as shown in FIG. 8, the power dividers 544 may be implemented on a small printed circuit board 741 that is mounted in the interior of a slot antenna 700 and the feed network 740 may comprise the printed circuit board 741 and respective transmission lines 750 that are connected to respective ones of a plurality of output pads 748 on the printed circuit board 741. Each transmission line 750 may be a metal wire that is pre-soldered to a respective one of the output pads 748. In some embodiments, an interior surface 714 of the tubular dielectric support 710 may have channels 716 formed therein that may be sized to receive respective metal wire transmission lines 750. The channels 716 may be formed, for example, during an extrusion process used to fabricate the tubular dielectric support 710. A distal end of each metal wire transmission line 750 may cross a respective one of the slots 530 so that each transmission line 750 may couple an RF signal thereon to the respective slot 530. Other components of the antenna 700 may be identical to the like numbered components of antenna 500, and hence further description thereof will be omitted here.

FIGS. 7A-7F are schematic diagrams illustrating example slot designs that may be used in the slot antennas according to embodiments of the present invention. In each of these figures, the slots 630 correspond to regions on a surface of the antenna that do not include metal. In other words, the antennas according to embodiments of the present invention may have a metal layer that includes one or more slots where metal is omitted.

As shown in FIGS. 7A-7F, a wide variety of different slot designs may be used. FIGS. 7A and 7B illustrate slot designs 600, 610 that may provide good cross-polarization performance. In particular, FIG. 7A illustrates a slot design 600 that includes a linear slot 602 that may extend, for example, parallel to the longitudinal axis of a tubular dielectric support such as the dielectric supports discussed above. Since the slot design 600 only includes the longitudinally-extending slot 602 and does not include any transverse slots, it may exhibit excellent cross-polarization performance. FIG. 7B illustrates a linear slot 610 that further includes tuning copper (or other metal) polygons 614. The tuning copper polygons 614 may be formed on the same copper layer of the flexible printed circuit board as the copper layer that defines the longitudinally-extending slot 602. As shown in FIG. 7B, only a small dielectric gap 616 separates the tuning copper polygons 614 from the main copper layer that defines the longitudinally-extending slot 602. The shape of the longitudinally-extending slot 602 may be readily modified by electrically connecting one or more of the tuning copper polygons 614 to the main copper layer that defines the longitudinally-extending slot 602. For example, one or more of the tuning copper polygons 614 may be short-circuited to the main copper layer that defines the longitudinally-extending slot 602 by using a soldering iron to deposit solder 618 in the small dielectric gap 616 separating one of the tuning copper polygons 614 from the main copper layer, as is shown schematically (using a dotted rectangle) on the right side of FIG. 7B. In this manner, the length of the slot 602 may be modified to tune the return loss and/or an elevation beamwidth of the antenna beam generated by a slot antenna according to embodiments of the present invention that includes the slot 610. The tuning copper polygons 614 typically do not have much of an impact on the performance of an antenna that includes the linear slot 610 when tuning copper polygons 614 are not electrically short-circuited to the main copper layer.

FIG. 7C illustrates a slot design 620 which may be used to decrease the overall size of the antenna. As shown in FIG. 7C, the slot design 620 includes a longitudinally-extending slot 622 and one or more transversely-extending slots 624 that may (but need not) extend generally perpendicular to the longitudinally-extending slot 622. The provision of the transversely-extending slots 624 may allow a decrease in the length of the longitudinally-extending slot 622 that will provide a desired elevation beamwidth, and thus may allow shortening the overall length of an antenna that includes the slot design 620. However, the inclusion of the transversely-extending slots 624 may degrade the cross-polarization performance of the antenna. FIG. 7D illustrates a slot design 630 which is identical to the slot design 620 except that slot design 630 further includes copper polygons 636 which may be used to tune the return loss and/or the elevation beamwidth of the antenna in the manner discussed above with reference to FIG. 7B.

FIG. 7E illustrates a slot design 640 which may be used to further decrease the overall size of the antenna. As shown in FIG. 7E, the slot design 640 includes a longitudinally-extending slot 642 and a pair of transversely-extending slots 644 that extend generally perpendicular to the longitudinally-extending slot 642. The transversely-extending slots 644 may be longer than the transversely-extending slots 624 in the slot designs 620, 630 of FIGS. 7C-7D, and hence the slot design 640 may allow a greater decrease in the length of the longitudinally-extending slot 642 that will provide a desired elevation beamwidth, and thus may allow further shortening the overall length of an antenna that includes the slot design 640. However, the inclusion of the longer transversely-extending slots 624 may further degrade the cross-polarization performance of the antenna. FIG. 7F illustrates a slot design 650 which is identical to the slot design 640 except that slot design 650 further includes copper polygons 656 which may be used to tune the return loss and/or the elevation beamwidth of the antenna in the manner discussed above with reference to FIG. 7B.

As discussed above, both the metal layer including the slots and the feed network may be arranged on either the interior or the exterior of the tubular dielectric support of slot antennas according to embodiments of the present invention. While not shown in the example embodiments above, the slot antennas will typically be enclosed within a radome which is used to protect the antenna from the environment (e.g., rain, animals, etc.). Typically, antenna radomes are formed of fiberglass that is generally transparent to RF energy. In some embodiments of the present invention, the radome may be used as the tubular dielectric support. This may potentially further reduce the size, weight and/or cost of the antenna.

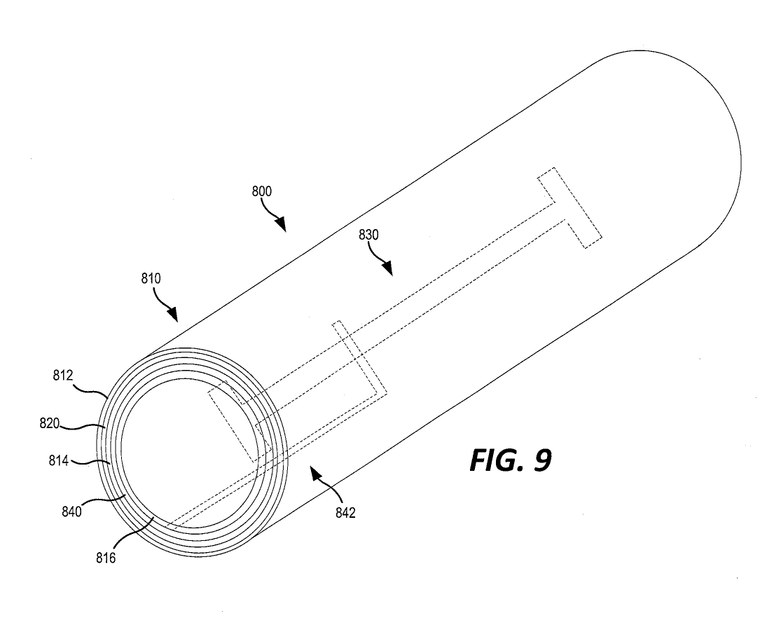

Radomes may be formed, for example, as layers of fiberglass material. Existing radome technology allows one or more layers of metal foil, with or without accompanying dielectric support layers, to be substituted for respective ones of the fiberglass layers of the radome. FIG. 9 schematically illustrates a slot antenna 800 that has this design. As shown in FIG. 9, the antenna 800 includes a multi-layer tubular radome 810 that includes five layers. Layers 812, 814 and 816 may comprise, for example, fiberglass layers. Layer 820 may comprise a layer that includes a patterned metal foil (which may or may not be formed on a separate dielectric support layer) in which a slot 830 is formed. Layer 840 may comprise a feed layer that includes a metal trace 842 that crosses the slot 830. A center conductor of a coaxial feed cable (not shown) may connect to the metal trace 842 and the ground conductor of the coaxial feed cable may be connected to the patterned metal foil of layer 820. The metal trace 842 may, for example, be capacitively coupled to the inner conductor of the coaxial cable through the fiberglass layer 816.

The slot antennas according to embodiments of the present invention may be used for standard cellular service. The antennas may be scaled appropriately to operate, for example, in the so-called “low band” (typically 696-960 MHz or selected portions thereof, although sometimes extending to lower frequencies such as the remainder of the 600 MHz band) and the so-called “high band” (typically about 1.6-2.7 GHz or selected portions thereof, although sometimes extending to lower frequencies such as the 1400 MHz band).

Embodiments of the present invention have been described above with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “on” another element, it can be directly on the other element or intervening elements may also be present. In contrast, when an element is referred to as being “directly on” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

Relative terms such as “below” or “above” or “upper” or “lower” or “horizontal” or “vertical” may be used herein to describe a relationship of one element, layer or region to another element, layer or region as illustrated in the figures. It will be understood that these terms are intended to encompass different orientations of the device in addition to the orientation depicted in the figures.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, operations, elements, and/or components, but do not preclude the presence or addition of one or more other features, operations, elements, components, and/or groups thereof.

Aspects and elements of all of the embodiments disclosed above can be combined in any way and/or combination with aspects or elements of other embodiments to provide a plurality of additional embodiments.

That which is claimed is:

1. A slot antenna for a cellular communications system, comprising:
a tubular dielectric support that extends along a longitudinal axis;
a metal layer that is substantially concentrically arranged with respect to the tubular dielectric support, the metal layer including a first longitudinally-extending slot therein in which metal is omitted;
a feed network that includes a transmission line that crosses the first longitudinally-extending slot.

2. The slot antenna of claim 1, wherein the metal layer comprises a metal pattern on a flexible printed circuit board.

3. The slot antenna of claim 1, wherein the metal layer comprises a plated metal pattern that is formed directly on the tubular dielectric support.

4. The slot antenna of claim 1, wherein the metal layer comprises a sheet metal pattern that is adhered to the tubular dielectric support.

5. The slot antenna of claim 1, wherein the feed network resides at least partially within the tubular dielectric support.

6. The slot antenna of claim 2, wherein the tubular dielectric support includes a longitudinally-extending slot.

7. The slot antenna of claim 6, wherein the flexible printed circuit board substantially covers the longitudinally-extending slot in the tubular dielectric support.

8. The slot antenna of claim 1, wherein a signal-carrying conductor of the transmission line is spaced apart from the metal layer and configured to capacitively couple with the metal layer.

9. The slot antenna of claim 1, wherein a ground plane of the transmission line is electrically connected to the metal layer.

10. The slot antenna of claim 1, wherein the transmission line comprises one of a plurality of transmission lines that are included in the feed network, and wherein the first longitudinally-extending slot is one of a plurality of longitudinally-extending slots in the metal layer, and wherein each transmission line crosses a respective one of the plurality of longitudinally-extending slots.

11. The slot antenna of claim 10, wherein an interior surface of the tubular dielectric support includes a plurality of channels that receive respective ones of the plurality of transmission lines.

12. The slot antenna of claim 11, wherein each transmission line comprises a respective metal wire.

13. The slot antenna of claim 12, wherein the feed network further comprises a printed circuit board having a plurality of power dividers that are configured to divide a radio frequency (RF) signal that is input to the feed network into a plurality of sub-components that are output along the respective transmission lines.

14. The slot antenna of claim 1, wherein the tubular dielectric support is hollow.

15. The slot antenna of claim 14, wherein the metal layer is within the hollow interior of the tubular dielectric support.

16. The slot antenna of claim 2, wherein the transmission line of the feed network is at least partly formed on the flexible printed circuit board.

17. The slot antenna of claim 1, wherein the metal layer circumferentially surrounds the tubular dielectric support.

18. A slot antenna for a cellular communications system, comprising:
a tubular dielectric support that extends along a longitudinal axis;
a metal cylinder on the tubular dielectric support, the metal cylinder including a first longitudinally-extending slot therein;
a feed network disposed at least partially within the tubular dielectric support that includes a transmission line that crosses the first longitudinally-extending slot.

19. The slot antenna of claim 18, wherein the metal cylinder comprises a metal pattern on a cylindrical flexible printed circuit board.

20. The slot antenna of claim 18, wherein the metal cylinder comprises a plated metal pattern that is formed directly on an exterior surface of the tubular dielectric support.

21. The slot antenna of claim 18, wherein the metal cylinder comprises a patterned and rolled piece of sheet metal pattern that is adhered to the tubular dielectric support.

22. The slot antenna of claim 19, wherein the tubular dielectric support includes a longitudinally-extending slot.

23. The slot antenna of claim 22, wherein the flexible printed circuit board substantially covers the longitudinally-extending slot in the tubular dielectric support.

24. The slot antenna of claim 18, wherein a signal-carrying conductor of the transmission line is spaced apart from the metal cylinder and configured to capacitively couple with the metal cylinder, and a ground plane of the transmission line is electrically connected to the metal cylinder.

25. A slot antenna for a cellular communications system, comprising:
a tubular dielectric support that extends along a longitudinal axis;
a flexible printed circuit board having metal layer that includes a plurality of slots therein in which metal is omitted, the flexible printed circuit board mounted to extend around a surface of the tubular dielectric support; and
a feed network having an input, a plurality of power dividers and a plurality of open-circuited transmission lines, each open-circuited transmission line crossing a respective one of the slots.

26. The slot antenna of claim 25, wherein the feed network is implemented at least in part as a second printed circuit board that is mounted within the tubular dielectric support.

27. The slot antenna of claim 25, wherein the feed network is implemented at least in part in the flexible printed circuit board.

28. The slot antenna of claim 25, wherein an interior surface of the tubular dielectric support tube includes a plurality of channels that receive respective ones of the plurality of transmission lines.

29. The slot antenna of claim 28, wherein each transmission line comprises a respective metal wire.

30. The slot antenna of claim 25, wherein the surface of the tubular dielectric support is an outer surface of the tubular dielectric support so that the flexible printed circuit board substantially circumferentially surrounds the tubular dielectric support.

31. The slot antenna of claim 25, wherein the tubular dielectric support has a mesh structure.
